(19) United States
(12) Patent Application Publication
(10) Pub. No.: US 2026/0180547 A1
(43) Pub. Date: Jun. 25, 2026

(54) FREQUENCY VARIATION REDUCTION FOR ELECTROACOUSTIC DEVICES

(71) Applicant: RF360 Singapore Pte. Ltd., Singapore (SG)

(72) Inventors: Michael MIRBACH, München (DE); Ghislain Michel RUPP, München (DE)

(21) Appl. No.: 18/990,214

(22) Filed: Dec. 20, 2024

(51) Int. Cl. H03H 9/02; H03H 9/56; H03H 9/64; H10N 30/20; H10N 30/87

(52) U.S. Cl. CPC H03H 9/02992; H03H 9/564; H03H 9/64; H10N 30/20; H10N 30/871

(57) ABSTRACT

Techniques and apparatus for designing and fabricating an electroacoustic device. One example method of fabricating an electroacoustic device generally includes forming a layer stack and forming an electrode structure above the layer stack. Forming the layer stack may include forming at least a portion of the layer stack with a thickness based on a positive slope of a function of a metallization ratio of the electrode structure versus the thickness of the at least the portion of the layer stack.

### TECHNICAL FIELD

Certain aspects of the present disclosure generally relate to electronic components and, more particularly, to electroacoustic devices.

### BACKGROUND

Electronic devices include traditional computing devices such as desktop computers, notebook computers, tablet computers, smartphones, wearable devices like a smartwatch, internet servers, and so forth. These various electronic devices provide information, entertainment, social interaction, security, safety, productivity, transportation, manufacturing, and other services to human users. These various electronic devices depend on wireless communications for many of their functions. Wireless communication systems and devices are widely deployed to provide various types of communication content such as voice, video, packet data, messaging, broadcast and so on. These systems may be capable of supporting communication with multiple users by sharing the available system resources (e.g., time, frequency, and power). Examples of such systems include code division multiple access (CDMA) systems, time division multiple access (TDMA) systems, frequency division multiple access (FDMA) systems, and orthogonal frequency division multiple access (OFDMA) systems, (e.g., a Long Term Evolution (LTE) system, or a New Radio (NR) system).

Wireless communication transceivers used in these electronic devices generally include multiple radio frequency (RF) filters for filtering a signal for a particular frequency or range of frequencies. Electroacoustic devices (e.g., “acoustic filters”) are used for filtering high-frequency (e.g., generally greater than 100 MHz) signals in many applications. Using a piezoelectric material as a vibrating medium, acoustic resonators operate by transforming an electrical signal wave that is propagating along an electrical conductor into an acoustic wave that is propagating via the piezoelectric material. The acoustic wave propagates at a velocity having a magnitude that is significantly less than that of the propagation velocity of the electromagnetic wave. Generally, the magnitude of the propagation velocity of a wave is proportional to a size of a wavelength of the wave. Consequently, after conversion of an electrical signal into an acoustic signal, the wavelength of the acoustic signal wave is significantly smaller than the wavelength of the electrical signal wave. The resulting smaller wavelength of the acoustic signal enables filtering to be performed using a smaller filter device. This permits acoustic resonators to be used in electronic devices having size constraints, such as the electronic devices enumerated above (e.g., particularly including portable electronic devices, such as smartphones).

Today, surface acoustic wave (SAW) or bulk acoustic wave (BAW) components may be used in wireless communication devices, such as for implementing RF filters. In SAW technology, the acoustic wave propagates laterally on a surface of a piezoelectric substrate, with the movement of the piezoelectric material generated by metal interdigital transducers (IDTs) on the surface. The wavelength of the acoustic wave may be defined by the pitch (e.g., the width of the metal finger and gap) of the IDT. In BAW technology, the acoustic wave propagates vertically through a three-dimensional structure, with an electric field applied through electrodes above and below a piezoelectric material. The wavelength, in this case, is approximately defined by the thickness of the piezoelectric material.

### SUMMARY

The systems, methods, and devices of the disclosure each have several aspects, no single one of which is solely responsible for its desirable attributes. Without limiting the scope of this disclosure as expressed by the claims which follow, some features will now be discussed briefly. After considering this discussion, and particularly after reading the section entitled “Detailed Description,” one will understand how the features of this disclosure provide advantages described herein.

Certain aspects of the present disclosure are directed to a method of fabricating an electroacoustic device. The method generally includes (i) forming a layer stack and (ii) forming an electrode structure above the layer stack, where forming the layer stack includes forming at least a portion of the layer stack with a thickness based on a positive slope of a function of a metallization ratio of the electrode structure versus the thickness of the at least the portion of the layer stack.

Certain aspects of the present disclosure provide an electroacoustic device. The electroacoustic device generally includes (i) a layer stack comprising a piezoelectric layer disposed above a substrate and (ii) an electrode structure disposed above the layer stack, where a thickness of at least a portion of the layer stack is associated with a positive slope of a function of a metallization ratio of the electrode structure versus the thickness of the at least the portion of the layer stack.

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

### BRIEF DESCRIPTION OF THE DRAWINGS

So that the manner in which the above-recited features of the present disclosure can be understood in detail, a more particular description, briefly summarized above, may be by reference to aspects, some of which are illustrated in the appended drawings. It is to be noted, however, that the appended drawings illustrate only certain aspects of this disclosure and are therefore not to be considered limiting of its scope, for the description may admit to other equally effective aspects.

FIG. 1A is a diagram of a perspective view of an example electroacoustic device, in which certain aspects of the present disclosure may be practiced.

FIG. 1B is a diagram of a cross-sectional view of the example electroacoustic device of FIG. 1A.

FIG. 2A is a top view of an example electrode structure of an electroacoustic device, in which certain aspects of the present disclosure may be practiced.

FIG. 2B is a top view of another example electrode structure of an electroacoustic device, in which certain aspects of the present disclosure may be practiced.

FIG. 3A is a diagram of a perspective view of an example electroacoustic device, in which certain aspects of the present disclosure may be practiced.

FIG. 3B is a diagram of a cross-sectional view of the example electroacoustic device of FIG. 3A.

FIG. 4A is an example graph with a curve representing metallization ratio versus thickness for an electroacoustic device, in accordance with certain aspects of the present disclosure.

FIG. 4B is an example graph with a curve representing frequency versus thickness for the electroacoustic device of FIG. 4A, in accordance with certain aspects of the present disclosure.

FIG. 5 is a flow diagram of example operations for fabricating an electroacoustic device, in accordance with certain aspects of the present disclosure.

FIG. 6 illustrates a schematic diagram and implementation of an example electroacoustic device, in accordance with certain aspects of the present disclosure.

FIG. 7 is a functional block diagram of at least a portion of an example simplified wireless transceiver circuit in which an electroacoustic device may be employed.

FIG. 8 is a diagram of an environment that includes an electronic device having a wireless transceiver such as the transceiver circuit of FIG. 7.

To facilitate understanding, identical reference numerals have been used, where possible, to designate identical elements that are common to the figures. It is contemplated that elements disclosed in one aspect may be beneficially utilized in other aspects without specific recitation.

### DETAILED DESCRIPTION

Certain aspects of the present disclosure generally relate to an electroacoustic device with reduced frequency variation and fabrication thereof. Such an electroacoustic device (e.g., a surface acoustic wave (SAW) filter or a thin-film surface acoustic wave (TF-SAW) filter) may include a layer stack and an electrode structure disposed above the layer stack. The thickness of at least a portion of the layer stack may be based on a positive slope of a function of a metallization ratio of the electrode structure versus the thickness of the at least the portion of the layer stack. In this manner, the thickness of the at least a portion of the layer stack and the metallization ratio of the electrode structure may be designed and fabricated accordingly to decrease the frequency variation of the electroacoustic device.

The detailed description set forth below in connection with the appended drawings is intended as a description of exemplary implementations and is not intended to represent the only implementations in which aspects of the present disclosure may be practiced. The term “exemplary” used throughout this description means “serving as an example, instance, or illustration,” and should not necessarily be construed as preferred or advantageous over other exemplary implementations. The detailed description includes specific details for the purpose of providing a thorough understanding of the exemplary implementations. In some instances, some devices are shown in block diagram form. Drawing elements that are common among the following figures may be identified using the same reference numerals.

### Example Electroacoustic Devices

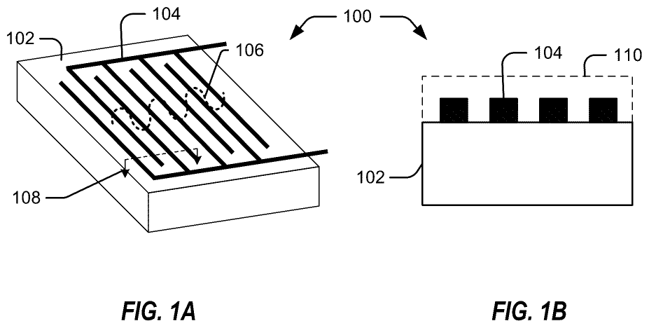

FIG. 1A is a diagram of a perspective view of an example electroacoustic device 100, in which certain aspects of the present disclosure may be practiced. The electroacoustic device 100 may be configured as or may be a portion of a surface acoustic wave (SAW) resonator. In certain descriptions herein, the electroacoustic device 100 itself may be referred to as a SAW resonator. However, there may be other electroacoustic device types that may be constructed based on the principles described herein.

The electroacoustic device 100 includes an electrode structure 104, that may be referred to as an interdigital transducer (IDT), on the surface of a piezoelectric material 102. The electrode structure 104 generally includes first and second comb-shaped electrode structures (electrically conductive and generally metallic) with electrode fingers extending from two busbars towards each other arranged in an interlocking manner in between the two busbars (e.g., arranged in an interdigitated manner, as shown). An electrical signal excited in the electrode structure 104 (e.g., applying an AC voltage) is transformed into an acoustic wave 106 that propagates in a particular direction via the piezoelectric material 102. The acoustic wave 106 is transformed back into an electrical signal and provided as an output. In many applications, the piezoelectric material 102 has a particular crystal orientation such that when the electrode structure 104 is arranged relative to the crystal orientation of the piezoelectric material 102, the acoustic wave mainly propagates in a direction perpendicular to the direction of the fingers (e.g., parallel to the busbars).

FIG. 1B is a diagram of a cross-sectional view of the electroacoustic device 100 of FIG. 1A along a cross-section 108 shown in FIG. 1A. The electroacoustic device 100 is illustrated by a simplified layer stack including the piezoelectric material 102 with the electrode structure 104 disposed on the piezoelectric material 102. The electrode structure 104 is electrically conductive and generally formed from metallic materials. The electrode structure 104 may alternatively be formed from materials that are electrically conductive, but non-metallic (e.g., graphene). The piezoelectric material 102 may be formed from a variety of materials such as quartz, lithium tantalate (LiTaO₃), lithium niobite (LiNbO₃), doped variants of these, other piezoelectric materials, or other crystals. The piezoelectric material 102 may be referred to as a “piezoelectric substrate,” but may also be referred to as a “piezoelectric layer,” such as in examples where there are additional layers below the piezoelectric material 102.

It should be appreciated that more complicated layer stacks including layers of various materials may be possible within the stack. For example, optionally, a temperature compensation layer 110 denoted by the dashed lines may be disposed above the electrode structure 104. The piezoelectric material 102 may be extended with multiple interconnected electrode structures disposed thereon to form a multi-resonator filter or to provide multiple filters. While not illustrated, when provided as an integrated circuit component, a cap layer may be provided over the electrode structure 104. The cap layer is applied so that a cavity is formed between the electrode structure 104 and an under surface of the cap layer. Electrical vias or bumps that allow the component to be electrically connected to connections on a substrate (e.g., via flip-chip or other techniques) may also be included.

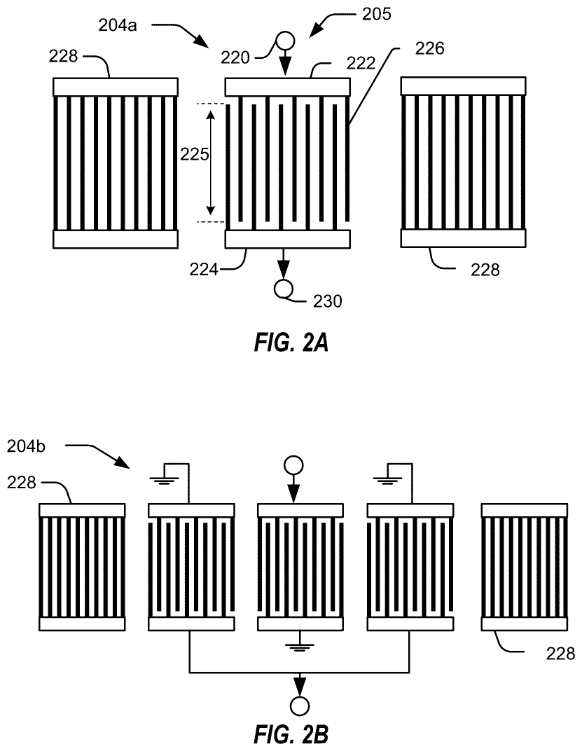

FIG. 2A is a top view of an example electrode structure 204a of an electroacoustic device, in which certain aspects of the present disclosure may be practiced. The electrode structure 204a has an IDT 205 that includes a first busbar 222 (e.g., first conductive segment or rail) electrically coupled to a first terminal 220 and a second busbar 224 (e.g., second conductive segment or rail) spaced from the first busbar 222 and coupled to a second terminal 230. A plurality of conductive fingers 226 are connected to either the first busbar 222 or the second busbar 224 in an interdigitated manner. Fingers 226 connected to the first busbar 222 extend towards the second busbar 224 but do not connect to the second busbar 224 so that there is a small gap between the ends of these fingers 226 and the second busbar 224. Likewise, fingers 226 connected to the second busbar 224 extend towards the first busbar 222 but do not connect to the first busbar 222 so that there is a small gap between the ends of these fingers 226 and the first busbar 222. Similarly, small gaps may also be formed between fingers 226 and any structure extending from the first busbar 222 or the second busbar 224 (e.g., stub fingers).

Between the busbars, there is an overlap region including a central region where a portion of one finger overlaps with a portion of an adjacent finger as illustrated by the central region 225. This central region 225 including the overlap may be referred to as the aperture, track, or active region where electric fields are produced between the fingers 226 to cause an acoustic wave to propagate in this region of the piezoelectric material 102. The periodicity of the fingers 226 is referred to as the pitch of the IDT. The pitch may be indicated in various ways. For example, in certain aspects, the pitch may correspond to a magnitude of a distance between fingers in the central region 225. This distance may be defined, for example, as the distance between center points of each of the fingers (and may be generally measured between a right (or left) edge of one finger and the right (or left) edge of an adjacent finger when the fingers have uniform width). In certain aspects, an average of distances between adjacent fingers may be used as the pitch. The frequency at which the piezoelectric material vibrates is a main resonance frequency of the electrode structure 204a. This frequency is determined at least in part by the pitch of the IDT 205 and other properties of the electroacoustic device 100.

The IDT 205 is arranged between two reflectors 228 which reflect the acoustic wave back towards the IDT 205 for the conversion of the acoustic wave into an electrical signal via the IDT 205 in the configuration shown and to prevent losses (e.g., confine and prevent escaping acoustic waves). Each reflector 228 has two busbars and a grating structure of conductive fingers that each connect to both busbars. The pitch of the reflector may be similar to or the same as the pitch of the IDT 205 to reflect acoustic waves in the resonant frequency range. But many configurations are possible.

When converted back to an electrical signal, the converted electrical signal may be provided as an output, such as to one of the first terminal 220 or the second terminal 230, while the other terminal may function as an input.

A variety of electrode structures are possible. FIG. 2A may generally illustrate a one-port configuration. Other configurations (e.g., two-port configurations) are also possible. For example, the electrode structure 204a may have an input IDT 205 where each terminal 220 and 230 functions as an input. In this event, an adjacent output IDT (not illustrated) that is positioned between the reflectors 228 and adjacent to the input IDT 205 may be provided to convert the acoustic wave propagating in the piezoelectric material 102 to an electrical signal to be provided at output terminals of the output IDT.

FIG. 2B is a top view of another example electrode structure 204b of an electroacoustic device, in which certain aspects of the present disclosure may be practiced. In this case, a dual-mode SAW (DMS) electrode structure 204b is illustrated, the DMS structure being a structure that may induce multiple resonances. The electrode structure 204b includes multiple IDTs arranged between reflectors 228 and connected as illustrated. The electrode structure 204b is provided to illustrate the variety of electrode structures in which principles described herein may be applied.

It should be appreciated that while a certain number of fingers 226 are illustrated, the number of actual fingers and length(s) and width(s) of the fingers 226 and busbars may be different in an actual implementation. Such parameters depend on the particular application and desired filter characteristics. In addition, a SAW filter may include multiple interconnected electrode structures each including multiple IDTs to achieve a desired passband (e.g., multiple interconnected resonators or IDTs to form a desired filter transfer function).

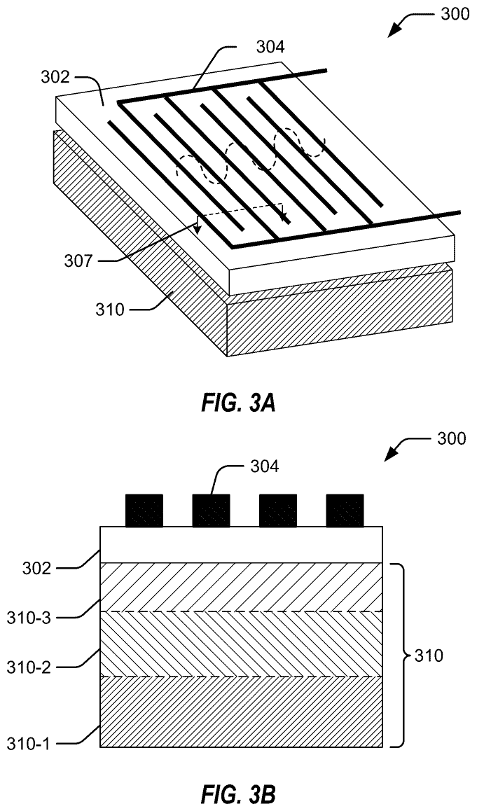

FIG. 3A is a diagram of a perspective view of another example of an electroacoustic device 300, in which certain aspects of the present disclosure may be practiced. The electroacoustic device 300 (e.g., that may be configured as or be a part of a SAW resonator) is similar to the electroacoustic device 100 of FIG. 1A but has a different layer stack. In particular, the electroacoustic device 300 includes a thin piezoelectric material 302 that is provided on a substrate 310 (e.g., silicon). The electroacoustic device 300 may be referred to as a thin-film SAW resonator (TF-SAW) in some cases. Based on the type of piezoelectric material 302 used (e.g., typically having higher coupling factors relative to the electroacoustic device 100 of FIG. 1A) and a controlled thickness of the piezoelectric material 302, the particular acoustic wave modes excited may be slightly different than those in the electroacoustic device 100 of FIG. 1A. Based on the design (thicknesses of the layers, and selection of materials, etc.), the electroacoustic device 300 may have a higher quality factor (Q) as compared to the electroacoustic device 100 of FIG. 1A. In general, the substrate 310 may be substantially thicker than the piezoelectric material 302 (e.g., on the order of 50 to 100 times thicker, or more). The substrate 310 may include other layers (or other layers may be included between the substrate 310 and the piezoelectric material 302).

FIG. 3B is a diagram of a cross-sectional view of the electroacoustic device 300 of FIG. 3A showing an exemplary layer stack (along a cross-section 307). In the example shown in FIG. 3B, the substrate 310 may include sublayers such as a substrate sublayer 310-1 (e.g., of silicon) that may have a higher resistance (e.g., relative to the other layers—a high resistivity layer). The substrate 310 may further include a trap rich layer 310-2 (e.g., polysilicon). The substrate 310 may further include a compensation layer 310-3 (e.g., silicon dioxide (SiO₂) or another dielectric material) that may provide temperature compensation and other properties. These sublayers may be considered part of the substrate 310 or their own separate layers. A relatively thin piezoelectric material 302 is provided on the substrate 310 with a particular thickness for providing a particular acoustic wave mode (e.g., as compared to the electroacoustic device 100 of FIG. 1A where the thickness of the piezoelectric material 102 may not be a significant design parameter beyond a certain thickness and may be generally thicker as compared to the piezoelectric material 302 of the electroacoustic device 300 of FIGS. 3A and 3B). The electrode structure 304 is positioned above the piezoelectric material 302. In addition, in some aspects, there may be one or more layers (not shown) possible above the electrode structure 304 (e.g., such as a thin passivation layer).

Based on the type of piezoelectric material, the thickness, and the overall layer stack, the coupling to the electrode structure 304 and acoustic velocities within the piezoelectric material in different regions of the electrode structure 304 may differ between different types of electroacoustic devices, such as between the electroacoustic device 100 of FIG. 1A and the electroacoustic device 300 of FIGS. 3A and 3B.

### Example Layer Stack Thickness Design for Low Frequency Variation

The production processes of electroacoustic devices (e.g., surface acoustic wave (SAW) devices, such as SAW filters) often have variations that result in high levels of frequency variation between electroacoustic devices. High frequency electroacoustic devices may be especially sensitive to frequency variations during production. As a result, a large number of the electroacoustic devices that are produced may be unsuitable for use, resulting in a low manufacturing yield.

The frequency variation of an electroacoustic device may be predominantly dependent on a thickness of a layer stack included in the electroacoustic device (e.g., a layer stack including a substrate and/or a piezoelectric layer) and a metallization ratio of an electrode structure included in the electroacoustic device. As used herein, the “metallization ratio” of an electroacoustic device (e.g., a SAW filter) generally refers to the ratio of the finger width to the finger pitch in the interdigital transducers (IDTs). The thickness of the layer stack and the metallization ratio of the electrode structure may have opposing impacts on the frequency (e.g., the resonant or filter frequency) of the electroacoustic device. For example, a higher layer stack thickness may result in a higher frequency for the electroacoustic device, whereas a higher metallization ratio may result in a lower frequency for the electroacoustic device. Some production processes for fabricating electroacoustic devices may attempt to independently minimize both layer stack thickness process variation and metallization ratio process variation in an effort to reduce frequency variation in the electroacoustic devices.

It has been discovered that there exists a relationship between a thickness of a layer stack included in an electroacoustic device and a metallization ratio of an electrode structure included in the electroacoustic device. The relationship may be a periodic dependence of the metallization ratio of the electrode structure on the thickness of the layer stack, and may be manifest as a swing curve. The periodic dependence may be caused by standing waves of incident light in the layer stack of an electroacoustic device during photo exposure. Depending on whether constructive or destructive interference is present, there may be a varying amount of light being coupled out of the substrate of the electroacoustic device into the photoresist of the electroacoustic device. The resulting additional rear side exposure of the photoresist may lead to a varying metallization ratio.

Certain aspects of the present disclosure are directed to an electroacoustic device with a layer stack and an electrode structure where at least a portion of the layer stack has a thickness based on a positive slope of a function of a metallization ratio of the electrode structure versus the thickness of the at least the portion of the layer stack. In this manner, the opposing effects of the thickness of the layer stack and the metallization ratio of the electrode structure may be controlled to compensate for one another (e.g., to effectively cancel each other out) and greatly decrease the frequency variation of electroacoustic devices during production. As a result, the number of produced electroacoustic device with an acceptable level of frequency variation may be increased (higher manufacturing yield).

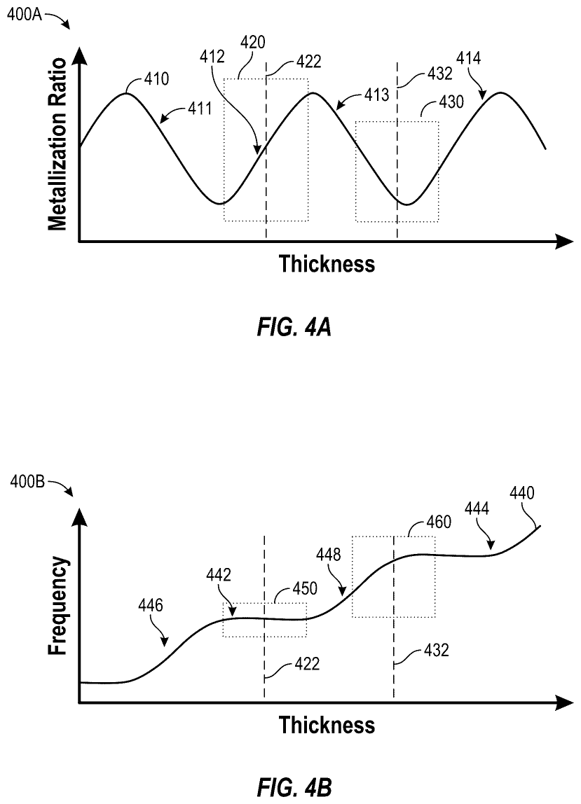

FIG. 4A is an example graph 400A with a curve 410 representing metallization ratio versus thickness (of a relevant portion of a layer stack) for an electroacoustic device (e.g., electroacoustic device 100 and 300 of FIGS. 1A, 1B, 3A, and 3B), in accordance with certain aspects of the present disclosure. The electroacoustic device may be, for example, a surface acoustic wave (SAW) filter or a thin-film surface acoustic wave (TF-SAW) filter.

The metallization ratio (the y-axis in FIG. 4A) may be the metallization ratio of an electrode structure (e.g., electrode structure 104 or electrode structure 304) of an electroacoustic device. In some cases, and as described above, the electrode structure may include a first comb-shaped electrode having a first set of fingers (e.g., conductive fingers 226) extending from a first busbar (e.g., first busbar 222) and a second comb-shaped electrode having a second set of fingers (e.g., conductive fingers 226) extending from a second busbar (e.g., second busbar 224), and the second set of fingers may be interdigitated with the first set of fingers. In these cases, the metallization ratio of the electrode structure may be based on widths of the first and second sets of fingers, and more specifically based on the widths of the first and second sets of fingers and the spacing between the fingers (e.g., the ratio of the finger width to the finger pitch).

The thickness (the x-axis in FIG. 4A) may be the thickness of at least a portion of a layer stack (e.g., the thickness of the piezoelectric material 102, as illustrated in FIGS. 1A-1B, or the thickness of at least the piezoelectric material 302 in a layer stack including piezoelectric material 302 and substrate 310, as illustrated in FIGS. 3A-3B). The thickness of the at least a portion of the layer stack described herein may be, for example, a thickness of the whole of the layer stack, a thickness of an optically relevant portion of the layer stack, or any portion of the layer stack. The optically relevant portion of a layer stack of an electroacoustic device may include, for example, any piezoelectric layer(s) (e.g., piezoelectric material 102 or piezoelectric material 302, which may be formed from a variety of materials such as quartz, lithium tantalate (LiTaO₃), lithium niobite (LiNbO₃), doped variants of these, other piezoelectric materials, or other crystals, as described above). In some aspects, the optically relevant portion of the layer stack may also include at least a portion of a substrate (e.g., a compensation layer in a substrate, such as compensation layer 310-3, which may include silicon dioxide (SiO₂) or another dielectric material, as described above).

As described above, a metallization ratio of an electrode structure included in an electroacoustic device (e.g., electroacoustic device 100 and 300 of FIGS. 1A, 1B, 3A, and 3B) may be dependent on a thickness of at least a portion of a layer stack included in the electroacoustic device. As a result, a function between the metallization ratio of the electrode structure and the thickness of the layer stack of the electroacoustic device may be used to determine a target thickness working point (e.g., a target thickness working point along a positive slope of the function) for at least a portion of a layer stack to use as a nominal thickness during electroacoustic device production. The function may be periodic and may be dependent on: (i) one or more optical properties of the layer stack of the electroacoustic device and/or (ii) a wavelength of a photolithography process used to fabricate the electroacoustic device. In some cases, the function may be determined using an optical reflectance simulation and/or high-density metrology on wafers with increased layer stack thickness variation.

The function between the metallization ratio of the electrode structure and the thickness of the at least a portion of the layer stack of an electroacoustic device may be represented by the curve 410 in the graph 400A. As illustrated, the metallization ratio of the electrode structure may have a periodic dependence on the thickness of the at least a portion of the layer stack, and this relationship may result in the curve 410 being sinusoidal, as illustrated. The curve 410 includes a number of positive swings (e.g., positively sloped portions 412 and 414) and a number of negative swings (e.g., negatively sloped portions 411 and 413) of the metallization ratio with thickness.

FIG. 4B is an example graph 400B with a curve 440 representing frequency versus thickness for the electroacoustic device of FIG. 4A, in accordance with certain aspects of the present disclosure. The frequency (the y-axis in FIG. 4B) may be the frequency of the electroacoustic device (e.g., the filter frequency of a SAW filter). As described above, the thickness (the x-axis in FIG. 4B) may be the thickness of at least a portion of a layer stack (e.g., the optically relevant portion of the layer stack).

As illustrated, the frequency of an electroacoustic device generally tends to increase as the thickness of the layer stack of the electroacoustic device increases. Specifically, at some portions of the curve 440 (e.g., portions 446 and 448), the frequency of the electroacoustic device may increase relatively rapidly as the thickness of the layer stack of the electroacoustic device increases. However, at some portions of the curve 440 (e.g., portions 442 and 444), the frequency of the electroacoustic device may remain relatively constant (and in some cases, frequency invariant), even as the thickness of the layer stack of the electroacoustic device increases. In graph 400B, region 450 illustrates a range of thicknesses where the frequency of the electroacoustic device may remain relatively constant, while region 460 illustrates a range of thicknesses where the frequency of the electroacoustic device increases. The range of layer stack thicknesses in region 420 of curve 410 in graph 400A corresponds to the range of layer stack thicknesses in region 450 of curve 440, and the range of layer stack thicknesses in region 430 of curve 410 in graph 400A corresponds to the range of layer stack thicknesses in region 460 of curve 440.

Using curve 410, a thickness where the metallization ratio has a positive slope (e.g., a portion of the curve 410 where increasing layer stack thickness leads to a higher metallization ratio) may be selected. For example, and as illustrated in FIG. 4A, a target layer stack thickness 422 (which may be at or near the center of the region 420 of the curve 410 where the metallization ratio has a positive slope) may be selected as the nominal thickness (also referred to as the “thickness working point”) for electroacoustic device production. In this manner, the frequencies of the fabricated electroacoustic devices may have little frequency variation, even as the thickness of the layer stack changes with process variations, as illustrated in corresponding region 450 of the curve 440. It is to be understood that any suitable point (or range) on any positively sloped portion of the curve 410 may be selected as the target thickness(es). In some cases, selecting the target layer stack thickness 422 in the center of the regions 420 and 450 as the thickness working point may allow for the occurrence of some layer stack thickness variations (e.g., resulting from the production processes used during the fabrication of the electroacoustic device) without significant negative impacts to the frequency variation of the electroacoustic device.

Regions of the curve 410 where the metallization ratio does not have a positive slope (or only has a positive slope for a small portion of the curve 410 in the region) may be avoided during electroacoustic device production, thereby circumventing (or at least reducing) frequency variation. For example, and as illustrated in FIG. 4A, region 430 of the curve 410 (where the metallization ratio does not consistently have a positive slope) and the accompanying center layer stack thickness 432 may be avoided for electroacoustic device production. In this manner, regions where the frequency of the electroacoustic device has increased variation with thickness, as illustrated in region 460 of the curve 440 where the frequency noticeably increases, may be avoided.

As described above, some production processes for fabricating electroacoustic devices may attempt to independently minimize both layer stack thickness process variation and metallization ratio process variation in an effort to reduce frequency variation in the electroacoustic devices. Aspects of the present disclosure may involve purposefully increasing the process variation of the metallization ratio of the electrode structure (e.g., by selecting a point along a positive slope of the function) to help compensate for the impact of the thickness of the layer stack on the frequency variation of an electroacoustic device.

### Example Operations for Fabricating an Electroacoustic Device

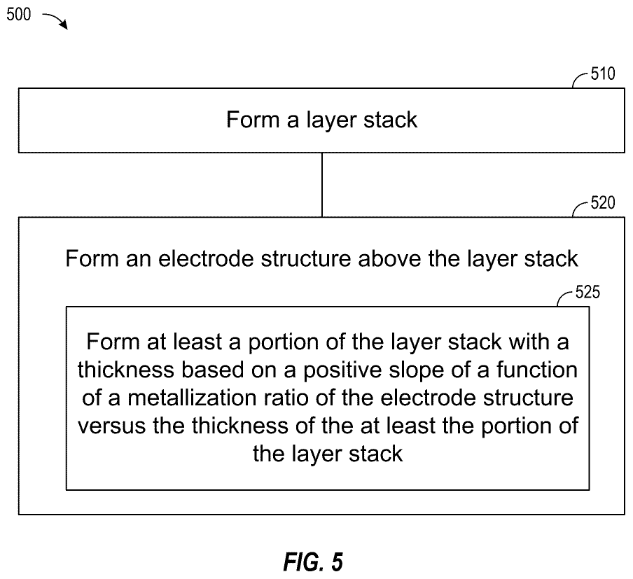

FIG. 5 is a flow diagram of example operations 500 for fabricating an electroacoustic device (e.g., electroacoustic device 100 and 300 of FIGS. 1A, 1B, 3A, and 3B), in accordance, with certain aspects of the present disclosure. In some cases, the electroacoustic device may include a surface acoustic wave (SAW) filter, such as a thin-film surface acoustic wave (TF-SAW) filter. The operations 500 are described in the form of a set of blocks that specify the operations that can be performed. However, the operations are not necessarily limited to the order shown in FIG. 5 or described herein, for the operations may be implemented in alternative orders or in fully or partially overlapping manners. Also, more, fewer, and/or different operations may be implemented to perform the operations 500. The operations 500 may be performed, for example, by a semiconductor fabrication facility (also referred to as a “fab house”) or other facility for electroacoustic device fabrication.

The operations 500 may include, at block 510, the fabrication facility forming a layer stack (e.g., piezoelectric material 102, or piezoelectric material 302 and substrate 310). According to certain aspects, forming the layer stack at block 510 may include the fabrication facility forming a substrate (e.g., substrate 310) and forming a piezoelectric layer (e.g., piezoelectric material 102 or piezoelectric material 302) above the substrate. In some cases, the substrate may include a dielectric material.

At block 520, the operations 500 may include the fabrication facility forming an electrode structure (e.g., electrode structure 104 or electrode structure 304) above the layer stack. In some cases, forming the layer stack may include, at block 520, the fabrication facility forming at least a portion of the layer stack with a thickness based on a positive slope (e.g., positively sloped portions 412 and 414) of a function of a metallization ratio of the electrode structure versus the thickness of the at least the portion of the layer stack (e.g., represented by curve 410). In some cases, the thickness of the at least the portion of the layer stack may include a thickness of a whole of the layer stack. The function may be a periodic function. In some cases, the function may be dependent on at least one of: (i) one or more optical properties of the layer stack or (ii) a wavelength of a photolithography process used to fabricate the electroacoustic device.

According to certain aspects, the operations 500 may include using photolithography. In this case, the thickness of the at least the portion of the layer stack may include a thickness of an optically relevant portion of the layer stack. The optically relevant portion of the layer stack may include, for example, any piezoelectric layer(s) (e.g., piezoelectric material 102 or piezoelectric material 302, which may be formed from a variety of materials such as quartz, lithium tantalate (LiTaO₃), lithium niobite (LiNbO₃), doped variants of these, other piezoelectric materials, or other crystals, as described above). In some aspects, the optically relevant portion of the layer stack may also include at least a portion of the substrate (e.g., a compensation layer in the substrate 310, such as compensation layer 310-3, which may include silicon dioxide (SiO₂) or another dielectric material, as described above).

### Example Applications of an Electroacoustic Device

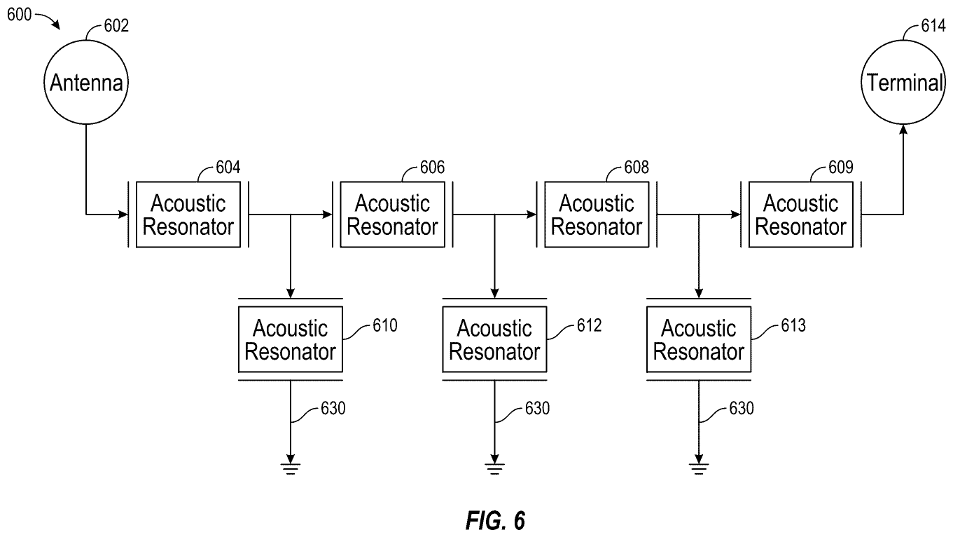

FIG. 6 illustrates a schematic diagram of an electroacoustic filter circuit 600 that may include an electroacoustic device with a thickness of at least a portion of a layer stack based on a positive slope of a function of a metallization ratio of an electrode structure versus the thickness of the at least the portion of the layer stack, in accordance with certain aspects of the present disclosure. The electroacoustic filter circuit 600 provides one example of where the disclosed SAW devices may be used. The electroacoustic filter circuit 600 includes an input terminal 602 and an output terminal 614. Between the input terminal 602 and the output terminal 614, a ladder-type network of SAW resonators is provided. The electroacoustic filter circuit 600 includes a first SAW resonator 604, a second SAW resonator 606, a third SAW resonator 608, and a fourth SAW resonator 609, all electrically connected in a series path between the input terminal 602 and the output terminal 614. A fifth SAW resonator 610 (e.g., a shunt resonator) has a first terminal connected between the first SAW resonator 604 and the second SAW resonator 606 and has a second terminal connected to a reference potential node 630 (e.g., electric ground) for the electroacoustic filter circuit 600. A sixth SAW resonator 612 (e.g., a shunt resonator) has a first terminal connected between the second SAW resonator 606 and the third SAW resonator 608 and has a second terminal connected to the reference potential node 630. A seventh SAW resonator 613 (e.g., a shunt resonator) has a first terminal connected between the third SAW resonator 608 and the fourth SAW resonator 609 and has a second terminal connected to the reference potential node 630.

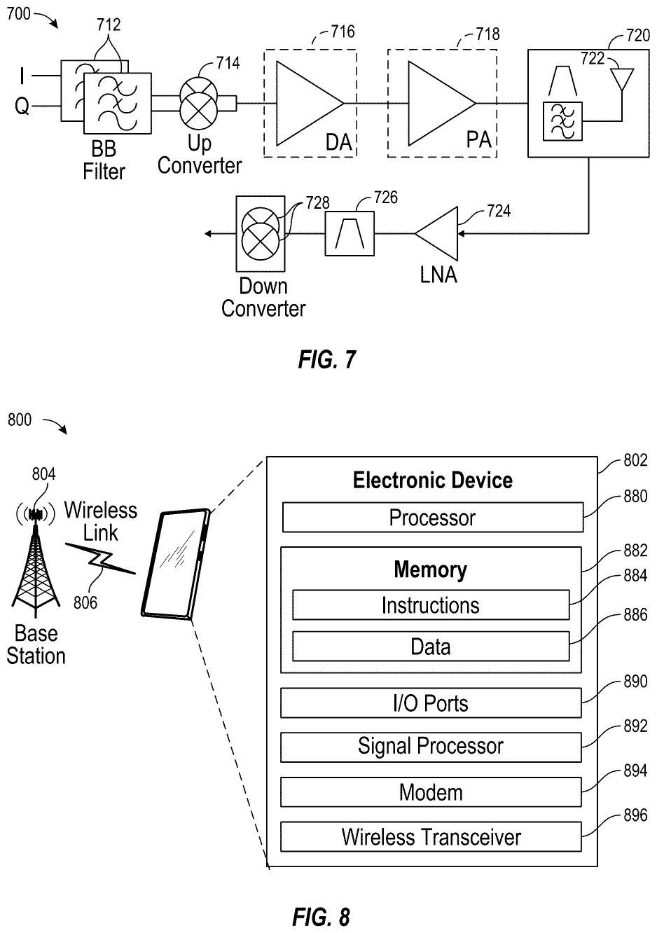

FIG. 7 is a functional block diagram of at least a portion of an example of a simplified wireless transceiver circuit 700 in which the electroacoustic filter circuit 600 of FIG. 6 (or other filters for wireless transmission using electroacoustic devices with a thickness of at least a portion of a layer stack based on a positive slope of a function of a metallization ratio of an electrode structure versus the thickness of the at least the portion of the layer stack, as described herein) may be employed. The transceiver circuit 700 is configured to receive signals/information for transmission (shown as in-phase (I) and quadrature (Q) values) which is provided to one or more baseband (BB) filters 712. The filtered output is provided to one or more mixers 714 for upconversion to radio frequency (RF) signals. The output from the one or more mixers 714 may be provided to a driver amplifier (DA) 716 whose output may be provided to a power amplifier (PA) 718 to produce an amplified signal for wireless transmission. The amplified signal is output to the antenna 722 through one or more filters 720 (e.g., duplexers if used as a frequency division duplex transceiver or other filters). The one or more filters 720 may include the electroacoustic filter circuit 600 of FIG. 6 (or other filters for wireless transmission using electroacoustic devices with a thickness of at least a portion of a layer stack based on a positive slope of a function of a metallization ratio of an electrode structure versus the thickness of the at least the portion of the layer stack, as described herein).

The antenna 722 may be used for both wirelessly transmitting and receiving signals. The transceiver circuit 700 includes a receive path through the one or more filters 720 to be provided to a low noise amplifier (LNA) 724 and a further filter 726 and then downconverted from the receive frequency to a baseband frequency through one or more mixer circuits 728 before the signal is further processed (e.g., provided to an analog-to-digital converter (ADC) and then demodulated or otherwise processed in the digital domain). There may be separate filters for the receive circuit (e.g., the receive circuit may have a separate antenna or have separate receive filters) that may be implemented using the electroacoustic filter circuit 600 of FIG. 6 (or another filter for wireless transmission using electroacoustic devices with a thickness of at least a portion of a layer stack based on a positive slope of a function of a metallization ratio of an electrode structure versus the thickness of the at least the portion of the layer stack, as described herein).

FIG. 8 is a diagram of an environment 800 that includes an electronic device 802, in which aspects of the present disclosure may be practiced. In the environment 800, the electronic device 802 communicates with a base station 804 (or other network node) through a wireless link 806. As shown, the electronic device 802 is depicted as a smartphone. However, the electronic device 802 may be implemented as any suitable computing or other electronic device, such as a cellular base station, broadband router, access point, cellular or mobile phone, gaming device, navigation device, media device, laptop computer, desktop computer, tablet computer, server computer, network-attached storage (NAS) device, smart appliance, vehicle-based communication system, Internet of Things (IoT) device, sensor or security device, asset tracker, extended reality device, wearable device, and so forth.

The base station 804 communicates with the electronic device 802 via the wireless link 806, which may be implemented as any suitable type of wireless link. Although depicted as a base station tower of a cellular radio network, the base station 804 may represent or be implemented as another device, such as a satellite, terrestrial broadcast tower, access point, peer-to-peer device, mesh network node, fiber optic line, another electronic device generally as described above, and so forth. Hence, the electronic device 802 may communicate with the base station 804 or another device via a wired connection, a wireless connection, or a combination thereof. The wireless link 806 can include a downlink of data or control information communicated from the base station 804 to the electronic device 802 and an uplink of other data or control information communicated from the electronic device 802 to the base station 804. The wireless link 806 may be implemented using any suitable communication protocol or standard, such as 3rd Generation Partnership Project (3GPP) Long-Term Evolution (LTE), 3GPP New Radio (NR) 5G, Institute of Electrical and Electronics Engineers (IEEE) 802.11, IEEE 802.15, IEEE 802.16, Bluetooth™, and so forth.

The electronic device 802 includes at least one processor 880 and at least one memory 882. The memory 882 may be or form a portion of a computer-readable storage medium. The processor 880 may include any type of processor, such as an application processor or a multi-core processor, that is configured to execute processor-executable instructions (e.g., code) stored by the memory 882. The memory 882 may include any suitable type of data storage media, such as volatile memory (e.g., random access memory (RAM)), non-volatile memory (e.g., flash memory), optical media, magnetic media (e.g., disk or tape), and so forth. In the context of this disclosure, the memory 882 is implemented to store instructions 884, data 886, and other information of the electronic device 802, and thus when configured as or part of a computer-readable storage medium, the memory 882 does not include transitory propagating signals or carrier waves.

The electronic device 802 may also include input/output ports 890. The I/O ports 890 enable data exchanges or interaction with other devices, networks, or users or between components of the device.

The electronic device 802 may further include at least one signal processor (SP) 892 (e.g., such as a digital signal processor (DSP)). The signal processor 892 may function similar to the processor and may be capable of executing instructions and/or processing information in conjunction with the memory 882.

For communication purposes, the electronic device 802 also includes a modem 894, a wireless transceiver 896, and an antenna (not shown). The wireless transceiver 896 provides connectivity to respective networks and other electronic devices connected therewith using radio-frequency (RF) wireless signals and may include the transceiver circuit 700 of FIG. 7. The wireless transceiver 896 may facilitate communication over any suitable type of wireless network, such as a wireless local area network (WLAN), a peer-to-peer (P2P) network, a mesh network, a cellular network, a wireless wide area network (WWAN), a navigational network (e.g., the Global Positioning System (GPS) of North America or another Global Navigation Satellite System (GNSS)), and/or a wireless personal area network (WPAN) (e.g., using ultra-wideband (UWB) technology).

### Example Aspects

In addition to the various aspects described above, specific combinations of aspects are within the scope of the disclosure, some of which are detailed below:

Aspect 1: A method of fabricating an electroacoustic device, the method comprising: forming a layer stack; and forming an electrode structure above the layer stack, wherein forming the layer stack comprises forming at least a portion of the layer stack with a thickness based on a positive slope of a function of a metallization ratio of the electrode structure versus the thickness of the at least the portion of the layer stack.

Aspect 2: The method of Aspect 1, wherein the thickness of the at least the portion of the layer stack comprises a thickness of a whole of the layer stack.

Aspect 3: The method of Aspect 1, wherein fabricating the electrode structure comprises using photolithography and wherein the thickness of the at least the portion of the layer stack comprises a thickness of an optically relevant portion of the layer stack.

Aspect 4: The method according to any of Aspects 1-3, wherein the electroacoustic device comprises a surface acoustic wave (SAW) filter.

Aspect 5: The method according to any of Aspects 1-3, wherein the electroacoustic device comprises a thin-film surface acoustic wave (TF-SAW) filter.

Aspect 6: The method according to any of Aspects 1-5, wherein forming the layer stack comprises: forming a substrate; and forming a piezoelectric layer above the substrate.

Aspect 7: The method of Aspect 6, wherein the substrate comprises a dielectric material.

Aspect 8: The method according to any of Aspects 1-7, wherein the function is a periodic function.

Aspect 9: The method according to any of Aspects 1-8, wherein the function is dependent on at least one of: one or more optical properties of the layer stack; or a wavelength of a photolithography process used to fabricate the electroacoustic device.

Aspect 10: An electroacoustic device comprising: a layer stack comprising a piezoelectric layer disposed above a substrate; and an electrode structure disposed above the layer stack, wherein a thickness of at least a portion of the layer stack is associated with a positive slope of a function of a metallization ratio of the electrode structure versus the thickness of the at least the portion of the layer stack.

Aspect 11: The electroacoustic device of Aspect 10, wherein the electroacoustic device comprises a surface acoustic wave (SAW) filter.

Aspect 12: The electroacoustic device of Aspect 10, wherein the electroacoustic device comprises a thin-film surface acoustic wave (TF-SAW) filter.

Aspect 13: The electroacoustic device according to any of Aspects 10-12, wherein: the electrode structure comprises a first comb-shaped electrode having a first set of fingers extending from a first busbar and a second comb-shaped electrode having a second set of fingers extending from a second busbar; the second set of fingers are interdigitated with the first set of fingers; and the metallization ratio of the electrode structure is based on widths of the first and second sets of fingers and pitches of the first and second sets of fingers.

Aspect 14: The electroacoustic device according to any of Aspects 10-13, wherein the thickness of the at least the portion of the layer stack comprises a thickness of a whole of the layer stack.

Aspect 15: The electroacoustic device according to any of Aspects 10-13, wherein the thickness of the at least the portion of the layer stack comprises a thickness of an optically relevant portion of the layer stack.

### Additional Considerations

The various operations of methods described above may be performed by any suitable means capable of performing the corresponding functions. The means may include various hardware and/or software component(s) and/or module(s).

As used herein, the term “determining” encompasses a wide variety of actions. For example, “determining” may include calculating, computing, processing, deriving, investigating, looking up (e.g., looking up in a table, a database, or another data structure), ascertaining, and the like. Also, “determining” may include receiving (e.g., receiving information), accessing (e.g., accessing data in a memory), and the like. Also, “determining” may include resolving, selecting, choosing, establishing, and the like.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage, or mode of operation. The term “coupled” is used herein to refer to the direct or indirect coupling between two objects. For example, if object A physically touches object B and object B touches object C, then objects A and C may still be considered coupled to one another—even if objects A and C do not directly physically touch each other. For instance, a first object may be coupled to a second object even though the first object is never directly physically in contact with the second object. The terms “circuit” and “circuitry” are used broadly and intended to include both hardware implementations of electrical devices and conductors that, when connected and configured, enable the performance of the functions described in the present disclosure, without limitation as to the type of electronic circuit.

The apparatus and methods described in the detailed description are illustrated in the accompanying drawings by various blocks, modules, components, circuits, steps, processes, algorithms, etc. (collectively referred to as “elements”). These elements may be implemented using hardware, for example.

One or more of the components, steps, features, and/or functions illustrated herein may be rearranged and/or combined into a single component, step, feature, or function or embodied in several components, steps, or functions. Additional elements, components, steps, and/or functions may also be added without departing from features disclosed herein. The apparatus, devices, and/or components illustrated herein may be configured to perform one or more of the methods, features, or steps described herein.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover at least: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c). All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112(f) unless the element is expressly recited using the phrase “means for” or, in the case of a method claim, the element is recited using the phrase “step for.”

It is to be understood that the claims are not limited to the precise configuration and components illustrated above. Various modifications, changes, and variations may be made in the arrangement, operation, and details of the methods and apparatus described above without departing from the scope of the claims.

What is claimed is:

1. A method of fabricating an electroacoustic device, the method comprising:
forming a layer stack; and
forming an electrode structure above the layer stack, wherein forming the layer stack comprises forming at least a portion of the layer stack with a thickness based on a positive slope of a function of a metallization ratio of the electrode structure versus the thickness of the at least the portion of the layer stack.

2. The method of claim 1, wherein the thickness of the at least the portion of the layer stack comprises a thickness of a whole of the layer stack.

3. The method of claim 1, wherein fabricating the electrode structure comprises using photolithography and wherein the thickness of the at least the portion of the layer stack comprises a thickness of an optically relevant portion of the layer stack.

4. The method of claim 1, wherein the electroacoustic device comprises a surface acoustic wave (SAW) filter.

5. The method of claim 1, wherein the electroacoustic device comprises a thin-film surface acoustic wave (TF-SAW) filter.

6. The method of claim 1, wherein forming the layer stack comprises:
forming a substrate; and
forming a piezoelectric layer above the substrate.

7. The method of claim 6, wherein the substrate comprises a dielectric material.

8. The method of claim 1, wherein the function is a periodic function.

9. The method of claim 1, wherein the function is dependent on at least one of:
one or more optical properties of the layer stack; or
a wavelength of a photolithography process used to fabricate the electroacoustic device.

10. An electroacoustic device comprising:
a layer stack comprising a piezoelectric layer disposed above a substrate; and
an electrode structure disposed above the layer stack, wherein a thickness of at least a portion of the layer stack is associated with a positive slope of a function of a metallization ratio of the electrode structure versus the thickness of the at least the portion of the layer stack.

11. The electroacoustic device of claim 10, wherein the electroacoustic device comprises a surface acoustic wave (SAW) filter.

12. The electroacoustic device of claim 10, wherein the electroacoustic device comprises a thin-film surface acoustic wave (TF-SAW) filter.

13. The electroacoustic device of claim 10, wherein:
the electrode structure comprises a first comb-shaped electrode having a first set of fingers extending from a first busbar and a second comb-shaped electrode having a second set of fingers extending from a second busbar;
the second set of fingers are interdigitated with the first set of fingers; and
the metallization ratio of the electrode structure is based on widths of the first and second sets of fingers and pitches of the first and second sets of fingers.

14. The electroacoustic device of claim 10, wherein the thickness of the at least the portion of the layer stack comprises a thickness of a whole of the layer stack.

15. The electroacoustic device of claim 10, wherein the thickness of the at least the portion of the layer stack comprises a thickness of an optically relevant portion of the layer stack.
